(19) United States
(12) Patent Application Publication
(10) Pub. No.: US 2026/0025001 A1
(43) Pub. Date: Jan. 22, 2026

(54) CONTROL METHOD FOR LARGE-SCALE DISTRIBUTED ENERGY RESOURCE MODEL IN SMART GRID

(71) Applicants: MARKETING SERVICE CENTER OF STATE GRID ZHEJIANG ELECTRIC POWER CO., LTD., Zhejiang (CN); STATE GRID ZHEJIANG ELECTRIC POWER CO., LTD., Zhejiang (CN)

(72) Inventors: GANG SUN, Zhejiang (CN); XIAO YANG, Zhejiang (CN); YULING CHEN, Zhejiang (CN); SHIJUN CHEN, Zhejiang (CN); JUNDA MA, Zhejiang (CN); CHUNGUANG LU, Zhejiang (CN); ZHONGHE HONG, Zhejiang (CN); RAN SHEN, Zhejiang (CN); PENGFEI LU, Zhejiang (CN); CHI JIANG, Zhejiang (CN); JIALI YU, Zhejiang (CN); RONGGUO HUANG, Zhejiang (CN); LINNA NI, Zhejiang (CN); JIAYING WANG, Zhejiang (CN); YI YU, Zhejiang (CN); YUHAO CHEN, Zhejiang (CN)

(21) Appl. No.: 18/775,181

(22) Filed: Jul. 17, 2024

(51) Int. Cl. H02J 3/38; B60L 53/80; G06F 30/18; G06Q 50/06

(52) U.S. Cl. CPC H02J 3/38; B60L 53/80; G06F 30/18; G06Q 50/06; H02J 2203/20

(57) ABSTRACT

A control method includes performing multi-level classification processing on distributed energy resources to obtain corresponding power supply equipment, power storage equipment, and hybrid equipment, analyzing and processing power distribution data and load data in the smart grid to obtain a power distribution demand of the smart grid, and dividing the smart grid into different division areas, determining corresponding power supply equipment, power storage equipment, or hybrid equipment in accordance with the power distribution demand and the division areas, and performing storage regulation and control on the corresponding power supply equipment, power storage equipment, or hybrid equipment, and if it is determined that the power supply equipment, power storage equipment, or hybrid equipment has a manner of multi-resource participation in the storage regulation and control, adding different multi-resource participation pricing strategies for power supply equipment, power storage equipment, or hybrid equipment in the different division areas.

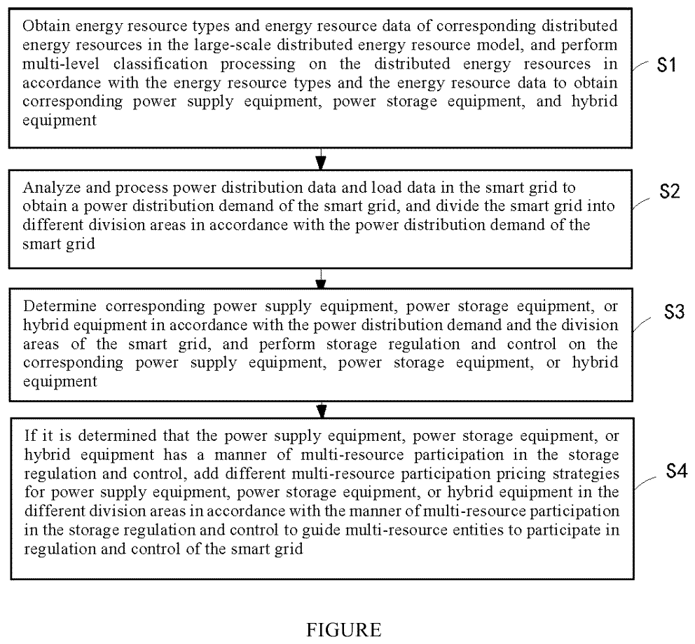

### BACKGROUND

### 1. Technical Field

The present invention relates to data technology, and in particular, to a control method for a large-scale distributed energy resource model in a smart grid.

### 2. Background Art

With the ever-growing global energy demand and the increasingly prominent environmental issues, smart grids, as an important development direction of future power systems, have received widespread attention. Smart grids utilize modern information technology and advanced power equipment to achieve efficient, safe, and reliable operation of power systems. Distributed energy resources play a more and more important role in smart grids. Automatic and intelligent control methods are of great significance for the efficient utilization and management of distributed energy resources.

Existing control methods for distributed energy resources mostly rely on a single type of energy equipment and lack comprehensive management and intelligent regulation and control of various energy equipment. Some methods in the prior art can only manage power generation or storage equipment, and they are difficult to achieve coordinated control of various energy equipment. Moreover, the determination of grid load and power distribution demand in the prior art is also relatively rough, and it is impossible to conduct fine regulation and control in accordance with specific demands of different areas, thereby resulting in a waste of resources and low operating efficiency.

Therefore, how to coordinately control various energy equipment and perform intelligent regulation and control depending on a grid demand, thereby improving the utilization efficiency of distributed energy resources and the operating efficiency of smart grids, has become an urgent problem to be solved.

### SUMMARY

The present invention provides a control method for a large-scale distributed energy resource model in a smart grid, which can coordinately control various energy equipment and perform intelligent regulation and control depending on a grid demand, thereby improving the utilization efficiency of distributed energy resources and the operating efficiency of the smart grid.

In a first aspect of an embodiment of the present invention, a control method for a large-scale distributed energy resource model in a smart grid is provided, including the following steps:
S1: obtaining energy resource types and energy resource data of corresponding distributed energy resources in the large-scale distributed energy resource model, and performing multi-level classification processing on the distributed energy resources in accordance with the energy resource types and the energy resource data to obtain corresponding power supply equipment, power storage equipment, and hybrid equipment;
S2: analyzing and processing power distribution data and load data in the smart grid to obtain a power distribution demand of the smart grid, and dividing the smart grid into different division areas in accordance with the power distribution demand of the smart grid;
S3: determining corresponding power supply equipment, power storage equipment, or hybrid equipment in accordance with the power distribution demand and the division areas of the smart grid, and performing storage regulation and control on the corresponding power supply equipment, power storage equipment, or hybrid equipment; and
S4: if it is determined that the power supply equipment, power storage equipment, or hybrid equipment has a manner of multi-resource participation in the storage regulation and control, adding different multi-resource participation pricing strategies for power supply equipment, power storage equipment, or hybrid equipment in the different division areas in accordance with the manner of multi-resource participation in the storage regulation and control to guide multi-resource entities to participate in regulation and control of the smart grid.

Optionally, in a possible implementation manner of the first aspect, the step S1 includes:
S11: obtaining the energy resource types of the corresponding distributed energy resources in the large-scale distributed energy resource model, where the energy resource types include power generation and supply information, power generation, storage, and supply information, and power storage and supply information;
S12: obtaining the energy resource data of the corresponding distributed energy resources in the large-scale distributed energy resource model, where the energy resource data includes grid-connectible power information and storable power information; and
S13: primarily classifying corresponding equipment in accordance with the power generation and supply information, the power generation, storage, and supply information, and the power storage and supply information to obtain power supply equipment and power storage equipment divided by function, and dividing the primarily classified power supply equipment and power storage equipment in accordance with the grid-connectible power information and the storable power information to obtain power supply equipment, power storage equipment, and hybrid equipment divided by status.

Optionally, in a possible implementation manner of the first aspect, the primarily classifying corresponding equipment in accordance with the power generation and supply information, the power generation, storage, and supply information, and the power storage and supply information to obtain power supply equipment and power storage equipment divided by function, and dividing the primarily classified power supply equipment and power storage equipment in accordance with the grid-connectible power information and the storable power information to obtain power supply equipment, power storage equipment, and hybrid equipment divided by status includes:
if it is determined that equipment of the distributed energy resources is the power generation and supply information, primarily classifying the corresponding equipment as the power supply equipment such as solar energy equipment;
if it is determined that equipment of the distributed energy resources is the power generation, storage, and supply information, primarily classifying the corresponding equipment as the power supply equipment such as a power station with a power storage function, and adding a secondary classification tag;
if it is determined that equipment of the distributed energy resources is the power storage and supply information, primarily classifying the corresponding equipment as the power storage equipment such as a battery swapping station, and adding a secondary classification tag; and
analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status.

Optionally, in a possible implementation manner of the first aspect, the analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status includes:
obtaining the storable power information of the power supply equipment in the secondary classification tag;
if it is determined that the storable power information is 0, taking the corresponding power supply equipment as secondarily classified power supply equipment; and
if it is determined that the storable power information is larger than 0, taking the corresponding power supply equipment as secondarily classified hybrid equipment.

Optionally, in a possible implementation manner of the first aspect, the analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status includes:
obtaining the grid-connectible power information and the storable power information of the power storage equipment in the secondary classification tag;
if it is determined that the storable power information is 0, taking the corresponding power storage equipment as secondarily classified power supply equipment; and
if it is determined that the grid-connectible power information is 0, taking the corresponding power storage equipment as secondarily classified power storage equipment; and
if it is determined that neither the storable power information nor the grid-connectible power information is 0, taking the corresponding power supply equipment as secondarily classified hybrid equipment.

Optionally, in a possible implementation manner of the first aspect, the step S2 includes:
S21: if it is determined that the power distribution data in the smart grid is larger than the load data, taking the power distribution demand of the smart grid as a power storage demand;
S22: if it is determined that the power distribution data in the smart grid is smaller than the load data, taking the power distribution demand of the smart grid as a grid connection demand; and
S23: obtaining power lines in the smart grid, segmenting the power lines in accordance with a preset distance to obtain different power distribution areas, and dividing the smart grid into the different division areas in accordance with the power storage demand or the grid connection demand.

Optionally, in a possible implementation manner of the first aspect, the obtaining power lines in the smart grid, segmenting the power lines in accordance with a preset distance to obtain different power distribution areas, and dividing the smart grid into the different division areas in accordance with the power storage demand or the grid connection demand includes:
obtaining load information in the different power distribution areas of the different areas of the smart grid in accordance with the load data;
calculating a power supply distance between each of the power distribution areas and a power supply source if it is determined that the power distribution demand of the smart grid is the power storage demand, and sorting the power distribution areas in accordance with the power supply distance and the load information to obtain a load demand sequence and the number of the areas;
sorting all the power distribution areas in descending order in accordance with the load information to obtain a load demand sequence and the number of the areas if it is determined that the power distribution demand of the smart grid is the grid connection demand; and
selecting corresponding power distribution areas in the load demand sequence as the division areas in accordance with the number of the areas.

Optionally, in a possible implementation manner of the first aspect, the calculating a power supply distance between each of the power distribution areas and a power supply source if it is determined that the power distribution demand of the smart grid is the power storage demand, and sorting the power distribution areas in accordance with the power supply distance and the load information to obtain a load demand sequence and the number of the areas includes:
obtaining a first endpoint of each of the power distribution areas on a side close to the power supply source, calculating a distance between the first endpoint and the power supply source to obtain the power supply distance between the corresponding power distribution area and the power supply source, and weighting the power supply distance in accordance with a distance weight to obtain a distance coefficient;
comparing a preset constant value with the load information to obtain a first proportional value, and weighting the first proportional value in accordance with a load weight to obtain a load coefficient;
adding the distance coefficient and the load coefficient together to obtain a first sorting coefficient, sorting the power distribution areas in ascending order in accordance with the first sorting coefficient to obtain the load demand sequence, and calculating a difference between the power distribution data and the load data to obtain the number of the areas; and
selecting corresponding areas in the load demand sequence in accordance with the number of the areas to obtain the different division areas.

Optionally, in a possible implementation manner of the first aspect, the adding the distance coefficient and the load coefficient together to obtain a first sorting coefficient, sorting the power distribution areas in ascending order in accordance with the first sorting coefficient to obtain the load demand sequence, and calculating a difference between the power distribution data and the load data to obtain the number of the areas includes:
calculating the first sorting coefficient and the number of the areas by the following formula:

$${p}_{1} = 1 \cdot {k}_{l} + \frac{u}{a} \cdot {k}_{u} , {s}_{1} = {z}_{1} + \frac{{w}_{1} - {w}_{2}}{{m}_{1}}$$

where p₁ is the first sorting coefficient, l is the power supply distance, kₗ is the distance weight, u is the preset constant value, a is the load information of the corresponding power distribution areas when the power distribution demand is the power storage demand, kᵤ is the load weight, s₁ is the number of the areas when the power distribution demand is the power storage demand, z₁ is a first basic number, w₁ is an electrical power value of the power distribution data, w₂ is an electrical power value of the load data, and m₁ is a first load normalization value.

Optionally, in a possible implementation manner of the first aspect, the sorting all the power distribution areas in descending order in accordance with the load information to obtain a load demand sequence and the number of the areas if it is determined that the power distribution demand of the smart grid is the grid connection demand includes:
calculating the number of the areas by the following formula:

$${s}_{2} = {z}_{2} + \frac{{w}_{2} - {w}_{1}}{{m}_{2}}$$

where s₂ is the number of the areas when the power distribution demand is the grid connection demand, z₂ is a second basic number, and m₂ is a second load normalization value.

Optionally, in a possible implementation manner of the first aspect, the step S3 includes:
A31: if it is determined that the power distribution demand of the smart grid is the power storage demand, determining the corresponding power storage equipment or hybrid equipment in the division areas;
A32: sorting in descending order to obtain a corresponding power storage sequence in accordance with the storable power information of the corresponding power storage equipment or hybrid equipment; and
A33: selecting power storage equipment or hybrid equipment within the power storage sequence in accordance with a storage demand value in the power storage demand, and performing the storage regulation and control on the selected power storage equipment or hybrid equipment in accordance with a power storage command when the storable power information of the corresponding power storage equipment or hybrid equipment is larger than or equal to the storage demand value.

Optionally, in a possible implementation manner of the first aspect, the step S3 includes:
B31: if it is determined that the power distribution demand of the smart grid is the grid connection demand, determining the corresponding power supply equipment or hybrid equipment in the division areas;
B32: sorting in descending order to obtain a corresponding grid connection sequence in accordance with the grid-connectible power information of the corresponding power supply equipment or hybrid equipment;
B33: selecting power supply equipment or hybrid equipment within the grid connection sequence in accordance with a grid connection value in the grid connection demand, and performing the storage regulation and control on the selected power supply equipment or hybrid equipment in accordance with a grid connection command when the grid connection information of the corresponding power supply equipment or hybrid equipment is larger than or equal to the grid connection demand value.

Optionally, in a possible implementation manner of the first aspect, the step S4 includes:
C41: if it is determined that the power storage equipment or hybrid equipment has the manner of multi-resource participation in the storage regulation and control, including a battery swapping party in the manner of multi-resource participation in the storage regulation and control, where the power storage equipment or hybrid equipment at least includes an electric vehicle battery swapping station;
C42: obtaining a first settlement price corresponding to the division areas and a power storage party, and obtaining first positioning information corresponding to the power storage equipment or hybrid equipment;
C43: obtaining second positioning information corresponding to power storage equipment or hybrid equipment in non-division areas;
C44: establishing an initial circular division area with an initial radius in accordance with the first positioning information; and
C45: calculating down regulation of the first settlement value in accordance with the circular division area, the first positioning information, and the second positioning information, where the first settlement value is a battery swapping price.

Optionally, in a possible implementation manner of the first aspect, the calculating down regulation of the first settlement value in accordance with the circular division area, the first positioning information, and the second positioning information includes:
if it is determined that the circular division area has the second positioning information, and the amount of the second positioning information is larger than or equal to a minimum amount, calculating a price adjustment coefficient;
if it is determined that the circular division area does not have the second positioning information or the amount of the second positioning information is smaller than the minimum amount, enlarging the circular division area in accordance with a preset strategy to obtain an updated radius and an updated circular division area, where the preset strategy includes a preset radius magnification factor;
if it is determined that the amount of updated second positioning information is larger than or equal to the minimum amount, calculating the price adjustment coefficient;
if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient; and
calculating the down regulation of the first settlement price in accordance with the price adjustment coefficient.

Optionally, in a possible implementation manner of the first aspect, the calculating the price adjustment coefficient and the down reduction of the first settlement price includes the following steps:
obtaining a first amount of the second positioning information in the circular division area, and a first separation distance between each of the second positioning information and the first positioning information;
obtaining a first number of amplifications corresponding to the circular division area, calculating the price adjustment coefficient in accordance with the first amount, the first separation distance, and the first number of amplifications, and calculating the down regulation of the first settlement price in accordance with the price adjustment coefficient; and
calculating the price adjustment coefficient and a down-regulated first settlement price by the following formula:

$${j}_{low} = {j}_{ori} - {j}_{ori} \cdot {v}_{low} , {v}_{low} = \frac{{\sum }_{U = 1}^{Y} {D}_{U}}{y} \cdot {K}_{D} + {E}_{low} \cdot {K}_{E} - {F}_{1} \cdot {K}_{F}$$

where j_{low} is the down-regulated first settlement price, jₒᵣᵢ is the original first settlement price, v_{low} is the price adjustment coefficient, F₁ is the first amount, K_{F} is a weight of the first amount, D_{U} is the first separation distance between the U-th second positioning information and the first positioning information, Y is an upper limit of the second positioning information, y is the amount of the second positioning information, K_{D} is a weight of the first separation distance, E_{low} is the first number of amplifications, and K_{E} is a weight of the first number of amplifications.

Optionally, in a possible implementation manner of the first aspect, the step S4 includes:
D41: if it is determined that the power supply equipment or hybrid equipment has the manner of multi-resource participation in the storage regulation and control, including a battery swapping party in the manner of multi-resource participation in the storage regulation and control, where the power supply equipment or hybrid equipment at least includes an electric vehicle battery swapping station;
D42: obtaining first positioning information corresponding to the power supply equipment or hybrid equipment;
D43: obtaining second positioning information corresponding to power supply equipment or hybrid equipment in non-division areas, and obtaining a second settlement price corresponding to the non-division areas of the second positioning information and a power storage party;
D44: establishing an initial circular division area with an initial radius in accordance with the first positioning information; and
D45: calculating down regulation of the second settlement values of all the second positioning information in accordance with the circular division area, the first positioning information, and the second positioning information, where the second settlement value is a battery swapping price.

Optionally, in a possible implementation manner of the first aspect, the calculating down regulation of the second settlement values of all the second positioning information in accordance with the circular division area, the first positioning information, and the second positioning information includes:
if it is determined that the circular division area has the second positioning information, and the amount of the second positioning information is larger than or equal to a minimum amount, calculating a price adjustment coefficient;
if it is determined that the circular division area does not have the second positioning information or the amount of the second positioning information is smaller than the minimum amount, enlarging the circular division area in accordance with a preset strategy to obtain an updated radius and an updated circular division area, where the preset strategy includes a preset radius magnification factor;
if it is determined that the amount of updated second positioning information is larger than or equal to the minimum amount, calculating the price adjustment coefficient;
if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient; and
calculating the down regulation of the second settlement price in accordance with the price adjustment coefficient.

Optionally, in a possible implementation manner of the first aspect, the calculating the price adjustment coefficient and the down reduction of the second settlement price includes the following steps:
obtaining a second amount of the second positioning information in the circular division area, and a second separation distance between each of the second positioning information and the first positioning information;
obtaining a second number of amplifications corresponding to the circular division area, calculating the price adjustment coefficient in accordance with the second amount, the second separation distance, and the second number of amplifications, and calculating the down regulation of the second settlement price in accordance with the price adjustment coefficient; and
calculating the price adjustment coefficient and a down-regulated second settlement price by the following formula:

$${r}_{low} = {r}_{ori} - {r}_{ori} \cdot {c}_{low} , {c}_{low} = \frac{{\sum }_{o = 1}^{X} {Q}_{o}}{x} \cdot {B}_{Q} + {A}_{low} \cdot {B}_{A} - {F}_{2} \cdot {B}_{F}$$

where r_{low} is the down-regulated second settlement price, rₒᵣᵢ is the original second settlement price, c_{low} is the price adjustment coefficient, F₂ is the second amount, B_{F} is a weight of the second amount, Qₒ is the second separation distance between the o-th second positioning information and the first positioning information, X is an upper limit of the second positioning information, x is the amount of the second positioning information, B_{Q} is a weight of the first separation distance, A_{low} is the second number of amplifications, and B_{A} is a weight of the second number of amplifications.

### Technical Effect I

This solution achieves multi-level classification processing of equipment of different types of distributed energy resources and, by obtaining energy resource types and energy resource data of the distributed energy sources, performs primary and secondary classification of the distributed energy resources. The primary classification divides the equipment by function in accordance with power generation and supply information, power generation, storage, and supply information, and power storage and supply information to obtain power supply equipment and power storage equipment. The secondary classification further divides the primarily classified equipment in accordance with grid-connectible power information and storable power information to obtain power supply equipment, power storage equipment, and hybrid equipment divided by status. This multi-level classification method greatly improves the equipment management accuracy and efficiency of the distributed energy resources and adapts to the diversified demands of the smart grid.

### Technical Effect II

This solution analyzes and processes power distribution data and load data in the smart grid to obtain a power distribution demand of the smart grid, and divides the smart grid into different division areas in accordance with the power distribution demand of the smart grid. By comparing the power distribution data and the load data, the method determines a power storage demand or grid connection demand of the smart grid and further divides the smart grid into detailed division areas. The division method not only improves the accuracy of smart grid regulation and control but also effectively manages and distributes energy resources, thereby improving the operating efficiency and stability of the smart grid.

### Technical Effect III

On the basis of multi-resource participation in storage regulation and control, this solution proposes multi-resource participation pricing strategies and, by adding the multi-resource participation pricing strategies, encourages multi-resource entities to participate in regulation of the smart grid. The strategies adjust settlement prices in accordance with the positioning information and division areas of different equipment, thereby allowing the equipment of the distributed energy resources to play a greater role in supply and demand regulation and optimizing the use of the energy resources. Through a scientific and reasonable price adjustment mechanism, more energy entities can be guided to participate in grid connection and storage, further improving the operating efficiency of the smart grid.

### BRIEF DESCRIPTION OF THE DRAWINGS

FIGURE is a flow chart of a control method for a large-scale distributed energy resource model in a smart grid provided by the present invention.

### DETAILED DESCRIPTION OF THE EMBODIMENTS

To make the objectives, technical solutions, and advantages of the embodiments of the present invention clearer, the following clearly and completely describes the technical solutions in the embodiments of the present invention with reference to the accompanying drawing in the embodiments of the present invention. Apparently, the described embodiments are only some but not all of the embodiments of the present invention. Based on the embodiments in the present invention, all other embodiments obtained by those of ordinary skill in the art without making creative labor shall fall within the scope of protection of the present invention.

The terms “first”, “second”, “third”, “fourth”, and so on (if any) in the specification and claims of the present invention and in the above accompanying drawing are intended to distinguish between similar objects but do not necessarily indicate a specific order or sequence. It should be understood that the data used in this way can be interchanged where appropriate so that the embodiments of the present invention described herein may be implemented in an order other than those illustrated or described herein.

It should be understood that the serial number of each step of various embodiments of the present invention does not indicate the execution sequence, which should be determined by the function and internal logic of the step, and shall not limit the implementation of the embodiments of the present invention.

It should be understood that, as used herein, the terms “including” and “having” as well as any variations thereof are intended to cover non-exclusive inclusions, for example, processes, methods, systems, products, or equipment that contains a series of steps or units is not necessarily limited to the steps or units explicitly listed, and may instead include other steps or units not explicitly listed or inherent to these processes, methods, products, or equipment.

It should be understood that, as used herein, “a plurality of” refers to two or more; the term “and/or” is merely an association relationship describing associated objects, indicating that there may be three relations, for example, A and/or B may indicate the following three cases: A exists individually, A and B exist simultaneously, and B exists individually; the character “/” generally indicates that the associated objects before and after the character form an “or” relation; “including A, B, and C” and “including A, B, C” mean that all three of A, B, and C are included, “including A, B, or C” means that one of A, B, and C is included, and “including A, B and/or C” means any one, two, or three of A, B, and C are included.

It should be understood that, as used herein, “B corresponding to A”, “A corresponding to B”, “A corresponds to B”, or “B corresponds to A” means that B is associated with A and B can be determined in accordance with A. Determining B in accordance with A does not mean that B is determined only in accordance with A but means that B can be determined in accordance with A and/or other information. Matching between A and B means that the similarity between A and B is greater than or equal to a preset threshold.

Depending on the context, the term “if” as used herein may be interpreted as “when”, or “in the case that”, or “in response to a determination”, or “in response to a detection”.

The technical solution of the present invention will be described in detail with reference to specific embodiments. The following specific embodiments can be combined with each other, and the same or similar concepts or processes may not be elaborated in some embodiments.

As shown in FIGURE, the present invention provides a control method for a large-scale distributed energy resource model in a smart grid, including the following implementation steps:
S1: obtaining energy resource types and energy resource data of corresponding distributed energy resources in the large-scale distributed energy resource model, and performing multi-level classification processing on the distributed energy resources in accordance with the energy resource types and the energy resource data to obtain corresponding power supply equipment, power storage equipment, and hybrid equipment.

This solution analyzes different types of energy resource data, performs multi-level classification processing on distributed energy resources, and divides equipment of the distributed energy resources into power supply equipment, power storage equipment, and hybrid equipment. First, a primary classification by function is performed to distinguish between the power supply equipment and the power storage equipment, and then a secondary classification by status is performed to obtain the final equipment category.

In some embodiments, the implementation manner of the step S1 includes:
S11: obtaining the energy resource types of the corresponding distributed energy resources in the large-scale distributed energy resource model, where the energy resource types include power generation and supply information, power generation, storage, and supply information, and power storage and supply information.

The power generation and supply information refers to equipment or systems that directly generate power, such as solar photovoltaic panels and wind turbines. The power generation, storage, and supply information refers to equipment or systems that can both generate and store power, such as solar power generation systems with batteries. The power storage and supply information refers to equipment or systems that are mainly used to store power for later use, such as battery energy storage systems and electric vehicle battery swapping stations.
S12: obtaining the energy resource data of the corresponding distributed energy resources in the large-scale distributed energy resource model, where the energy resource data includes grid-connectible power information and storable power information.

The grid-connectible power information relates to power data of equipment or systems that can be directly connected to the smart grid and supply power. The storable power information includes power data of equipment or systems that can store power for use during non-service periods.
S13: primarily classifying corresponding equipment in accordance with the power generation and supply information, the power generation, storage, and supply information, and the power storage and supply information to obtain power supply equipment and power storage equipment divided by function, and dividing the primarily classified power supply equipment and power storage equipment in accordance with the grid-connectible power information and the storable power information to obtain power supply equipment, power storage equipment, and hybrid equipment divided by status.

This solution first performs a primary classification in accordance with the power generation and supply information, the power generation, storage, and supply information, and the power storage and supply information to identify power supply equipment and power storage equipment divided by function, and then divides the primarily classified equipment by status in accordance with the grid-connectible power information and the storable power information to further identify power supply equipment, power storage equipment, and hybrid equipment divided by status.

In some embodiments, the implementation manner of the step S13 includes:
S131: if it is determined that equipment of the distributed energy resources is the power generation and supply information, primarily classifying the corresponding equipment as the power supply equipment.

This solution performs a primary classification and a secondary classification on the equipment of the distributed energy resources to manage and control these equipment more accurately. If the equipment is mainly used to generate power, that is, it has no power storage capability, then such equipment is primarily classified as the power supply equipment.
S132: if it is determined that equipment of the distributed energy resources is the power generation, storage, and supply information, primarily classifying the corresponding equipment as the power supply equipment, and adding a secondary classification tag.

For equipment that can both generate and store power, they are first primarily classified as the power supply equipment, but at the same time, they are given a secondary classification tag to indicate that they need to be further classified.
S133: if it is determined that equipment of the distributed energy resources is the power storage and supply information, primarily classifying the corresponding equipment as the power storage equipment, and adding a secondary classification tag.

If the equipment is mainly used to store power, then such equipment is primarily classified as the power storage equipment and given a secondary classification tag to distinguish it from other functions.
S134: analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status.

It should be noted that this solution further analyzes the power supply equipment and the power storage equipment with the secondary classification tag to determine whether they can be connected to the smart grid or have additional power storage information.

In some embodiments, the implementation manner of the step S134 includes:
S1341: obtaining the storable power information of the power supply equipment in the secondary classification tag.

First, the storable power information of the power supply equipment is collected, and then determined and classified.
S1342: if it is determined that the storable power information is 0, taking the corresponding power supply equipment as secondarily classified power supply equipment.

If the storable power information of the power supply equipment is 0, that is, it cannot continue to store power, then such equipment still remains to be power supply equipment after the secondary classification.
S1343: if it is determined that the storable power information is larger than 0, taking the corresponding power supply equipment as secondarily classified hybrid equipment.

If the storable power information of the power supply equipment is larger than 0, it indicates that such equipment can both supply and store power, so they are classified as the hybrid equipment after the secondary classification. It should be noted that the smart grid is capable of identifying which equipment can supply power, which equipment can store power, and which equipment has hybrid capabilities. This helps reallocate resources when necessary, especially during peak demand or supply shortages. Through the above-described primary and secondary classification processes, the smart grid manages the equipment of the distributed energy resources more effectively and ensures that the power supply and scheduling are more reasonable and efficient. This classification method helps improve the operating performance of the smart grid, achieve optimal allocation of energy resources, and respond to different power supply and storage demands, which is critical to achieving the economy and reliability of the smart grid.

In some embodiments, the implementation manner of the step S134 includes:
S1344: obtaining the grid-connectible power information and the storable power information of the power storage equipment in the secondary classification tag.

First, the secondary classification tag information of all the power supply equipment is obtained from a smart grid management system, including the grid-connectible power information and the storable power information thereof.
S1345: if it is determined that the storable power information is 0, taking the corresponding power storage equipment as secondarily classified power supply equipment.

The storable power information of such equipment is checked. If the storable power information of some equipment is 0, that is, it currently does not have the function or capability to store power, then such equipment should be classified as secondarily classified power supply equipment.
S1346: if it is determined that the grid-connectible power information is 0, taking the corresponding power storage equipment as secondarily classified power storage equipment.

The grid-connectible power information of such equipment is checked. If the grid-connectible power information of some equipment is 0, that is, it currently does not have the function or capability to connect to the smart grid for power supply, then such equipment should be classified as secondarily classified power storage equipment.
S1347: if it is determined that neither the storable power information nor the grid-connectible power information is 0, taking the corresponding power supply equipment as secondarily classified hybrid equipment.

If neither the storable power information nor the grid-connectible power information of some equipment is 0, that is, it can both supply power to the smart grid and store power, then such equipment should be classified as the hybrid equipment. By this classification method, the smart grid manages and schedules various types of equipment more flexibly, thus ensuring that the smart grid can achieve optimal power supply and storage effects under different operating conditions and demands, and enhance the stability and reliability thereof.
S2: analyzing and processing power distribution data and load data in the smart grid to obtain a power distribution demand of the smart grid, and dividing the smart grid into different division areas in accordance with the power distribution demand of the smart grid.

This solution describes a method to analyze and process power distribution data and load data in the smart grid to obtain a power distribution demand of the smart grid, and then divide the smart grid into different division areas.

In some embodiments, the implementation manner of the step S2 includes:
S21: if it is determined that the power distribution data in the smart grid is larger than the load data, taking the power distribution demand of the smart grid as a power storage demand.

First, the power distribution data (i.e., the power supplied by the smart grid) and the load data (i.e., the power required by the smart grid) are collected from the smart grid. If the power distribution data is larger than the load data, it indicates that the current power supply of the smart grid exceeds the consumer demand, so there is a power storage demand, that is, a method to store excess power is required.
S22: if it is determined that the power distribution data in the smart grid is smaller than the load data, taking the power distribution demand of the smart grid as a grid connection demand.

If the power distribution data is smaller than the load data, it indicates that the current power supply of the smart grid is lower than the consumer demand, so there is a grid connection demand, that is, more power needs to be obtained from the outside to meet the load demand.
S23: obtaining power lines in the smart grid, segmenting the power lines in accordance with a preset distance to obtain different power distribution areas, and dividing the smart grid into the different division areas in accordance with the power storage demand or the grid connection demand.

It is necessary to obtain power line information in the smart grid because it is the basis for dividing the power distribution areas of the smart grid. The power lines are segmented in accordance with a preset distance (such as a preset wire transmission distance), and then the smart grid is divided into different power distribution areas. This can be determined in accordance with the physical structure of the smart grid. Finally, the smart grid is divided into different division areas in accordance with the obtained power storage demand or grid connection demand. For example, if there is a power storage demand in an area, priority may be given to deploying power storage equipment; if there is a grid connection demand in another area, equipment may need to be connected to the smart grid.

In some embodiments, the implementation manner of the step S23 includes:
S231: obtaining load information in the different power distribution areas of the different areas of the smart grid in accordance with the load data.

This solution requires obtaining load information in the different power distribution areas of the different areas of the smart grid, which involves analyzing the power consumption in each of the areas.
S232: calculating a power supply distance between each of the power distribution areas and a power supply source if it is determined that the power distribution demand of the smart grid is the power storage demand, and sorting the power distribution areas in accordance with the power supply distance and the load information to obtain a load demand sequence and the number of the areas.

If it is the power storage demand, indicating excess power, this solution calculates a power supply distance between each of the power distribution areas and a power supply source (such as a power station). Then, the power distribution areas are sorted in accordance with the power supply distance and the load information to generate a load demand sequence. The implementation manner is explained below.

In some embodiments, the implementation manner of the step S232 includes:
S2321: obtaining a first endpoint of each of the power distribution areas on a side close to the power supply source, calculating a distance between the first endpoint and the power supply source to obtain the power supply distance between the corresponding power distribution area and the power supply source, and weighting the power supply distance in accordance with a distance weight to obtain a distance coefficient.

First, this solution considers a distance dimension to calculate a distance coefficient and identifies a first endpoint of each of the power distribution areas on a side close to the power supply source (such as a power station); then, the actual physical distance from the first endpoint to the power supply source is calculated, and the resulting power supply distance is multiplied by a distance weight to obtain a weighted distance coefficient, where the distance weight can be preset manually. It can be understood that the greater the power supply distance, the greater the corresponding distance coefficient. It should be noted that in a scenario of excess power, the greater the distance, the greater the power loss during power storage, and the further back it will be in subsequent sorting.
S2322: comparing a preset constant value with the load information to obtain a first proportional value, and weighting the first proportional value in accordance with a load weight to obtain a load coefficient.

For the load dimension, a preset constant value is compared with the load information of the corresponding power distribution areas to obtain a first proportional value, and then the first proportional value is multiplied by a load weight to obtain a load coefficient, where the load weight can be preset manually. It can be understood that the greater the load information, the smaller the first proportion value, and the smaller the corresponding load coefficient. It should be noted that in a scenario of excess power, the larger the load, the greater the power consumption, and the corresponding area is less suitable for power storage and will be further back in subsequent sorting.
S2323: adding the distance coefficient and the load coefficient together to obtain a first sorting coefficient, sorting the power distribution areas in ascending order in accordance with the first sorting coefficient to obtain the load demand sequence, and calculating a difference between the power distribution data and the load data to obtain the number of the areas.

After obtaining the distance coefficient and the load coefficient, this solution combines the data of the two dimensions to obtain a first sorting coefficient, and then sorts the power distribution areas with smaller first sorting coefficients in front and selects them first. At the same time, this solution further calculates the number of the areas in accordance with a difference between the power distribution data and the load data. The larger the difference, the greater the demand and the more the number of the corresponding areas.

In some embodiments, the implementation manner of the step S2323 includes:
calculating the first sorting coefficient and the number of the areas by the following formula:

$${p}_{1} = l \cdot {k}_{l} + \frac{u}{a} \cdot {k}_{u} , {s}_{1} = {z}_{1} + \frac{{w}_{1} - {w}_{2}}{{m}_{1}}$$

where p₁ is the first sorting coefficient, l is the power supply distance, kₗ is the distance weight, u is the preset constant value, a is the load information of the corresponding power distribution areas when the power distribution demand is the power storage demand, kᵤ is the load weight, s₁ is the number of the areas when the power distribution demand is the power storage demand, z₁ is a first basic number, w₁ is an electrical power value of the power distribution data, w₂ is an electrical power value of the load data, and m₁ is a first load normalization value.

In the above formula, l·kₗ is the distance coefficient, and

$$\frac{u}{a} \cdot {k}_{u}$$

is the load coefficient. The larger the corresponding coefficients, the larger the first sorting coefficient obtained.

$$\frac{{w}_{2} - {w}_{1}}{{m}_{2}}$$

is the difference coefficient. The larger the difference, the larger the corresponding coefficient, which makes the number of the areas when the power distribution demand is the power storage demand larger. The first load normalization value and the first basic number may be preset by staff. By the above-described calculation method, the power distribution areas can be systematically sorted and the division areas of the smart grid under the power storage demand can be determined accordingly. This method operates in accordance with the actual operation data of the smart grid and combines the distance and load weights to optimize the power distribution and storage strategy, thereby improving the efficiency and power supply reliability of the smart grid.
S2324: selecting corresponding areas in the load demand sequence in accordance with the number of the areas to obtain the different division areas.

This solution selects corresponding areas in the load demand sequence in accordance with the number of the areas to obtain the different division areas. It can be understood that the division areas are areas where power storage is performed.
S233: sorting all the power distribution areas in descending order in accordance with the load information to obtain a load demand sequence and the number of the areas if it is determined that the power distribution demand of the smart grid is the grid connection demand.

If it is the grid connection demand, indicating insufficient power, this solution needs to sort all the power distribution areas in descending order in accordance with the load information and place the areas with higher loads in front in the sequence. Similarly, in accordance with the load demand sequence obtained by sorting and the actual demand, the number of to-be-divided power distribution areas is determined.

In some embodiments, the implementation manner of the step S233 includes:
calculating the number of the areas by the following formula:

$${s}_{2} = {z}_{2} + \frac{{w}_{2} - {w}_{1}}{{m}_{2}}$$

where s₂ is the number of the areas when the power distribution demand is the grid connection demand, z₂ is a second basic number, and m₂ is a second load normalization value.

In the above formula,

$$\frac{{w}_{2} - {w}_{1}}{{m}_{2}}$$

is the demand coefficient. The larger the load, the larger the number of the areas when the power distribution demand is the grid connection demand. The second load normalization value and the second basic number may be preset by staff.
S234: selecting corresponding power distribution areas in the load demand sequence as the division areas in accordance with the number of the areas.

Finally, corresponding power distribution areas in the load demand sequence are selected as the division areas in accordance with the number of the areas. The division areas at this time are areas where grid connection is required.
S3: determining corresponding power supply equipment, power storage equipment, or hybrid equipment in accordance with the power distribution demand and the division areas of the smart grid, and performing storage regulation and control on the corresponding power supply equipment, power storage equipment, or hybrid equipment.

This solution considers three scenarios: power storage demand, grid connection demand, and multi-resource participation in storage regulation and control, each of which has its specific process and operation steps.

In some embodiments, the implementation manner of the step S3 includes:
A31: if it is determined that the power distribution demand of the smart grid is the power storage demand, determining the corresponding power storage equipment or hybrid equipment in the division areas.

When the power distribution demand of the smart grid is the power storage demand, the server needs to divide areas in the smart grid and determine those equipment with a power storage function in these areas. Such equipment can be specialized power storage equipment or hybrid equipment with a power storage function.
A32: sorting in descending order to obtain a corresponding power storage sequence in accordance with the storable power information of the corresponding power storage equipment or hybrid equipment.

Next, these power storage equipment or hybrid equipment are sorted in descending order by storage capacity to form a power storage sequence. It can be understood that the equipment ranking highly in the sequence has a larger storage capacity.
A33: selecting power storage equipment or hybrid equipment within the power storage sequence in accordance with a storage demand value in the power storage demand, and performing the storage regulation and control on the selected power storage equipment or hybrid equipment in accordance with a power storage command when the storable power information of the corresponding power storage equipment or hybrid equipment is larger than or equal to the storage demand value.

Then, in accordance with the specific power storage demand of the smart grid, one or more pieces of equipment with their power storage information meeting or exceeding the required storage capacity are selected from the power storage sequence, and a power storage instruction is issued to these equipment to perform power storage operations.

In some embodiments, the implementation manner of the step S3 includes:
B31: if it is determined that the power distribution demand of the smart grid is the grid connection demand, determining the corresponding power supply equipment or hybrid equipment in the division areas.

If the power distribution demand of the smart grid is the grid connection demand, that is, the power needs to be transmitted to the smart grid for use by other users, then the equipment that can supply power in the areas is determined first, and such equipment can be specialized power supply equipment or hybrid equipment with a power supply function.
B32: sorting in descending order to obtain a corresponding grid connection sequence in accordance with the grid-connectible power information of the corresponding power supply equipment or hybrid equipment.

Next, in accordance with the grid-connectible power information of these power supply equipment or hybrid equipment, they are sorted in descending order to form a grid connection sequence, that is, a power supply sequence, and the equipment ranking highly in the grid connection sequence has greater grid-connectible power.
B33: selecting power supply equipment or hybrid equipment within the grid connection sequence in accordance with a grid connection value in the grid connection demand, and performing the storage regulation and control on the selected power supply equipment or hybrid equipment in accordance with a grid connection command when the grid connection information of the corresponding power supply equipment or hybrid equipment is larger than or equal to the grid connection demand value.

In accordance with the grid connection demand, this solution can select from the power supply sequence one or more pieces of equipment with their grid-connectible power information meeting or exceeding the required grid connection capacity, and issue a grid connection instruction to these equipment to perform power supply operations.
S4: if it is determined that the power supply equipment, power storage equipment, or hybrid equipment has a manner of multi-resource participation in the storage regulation and control, adding different multi-resource participation pricing strategies for power supply equipment, power storage equipment, or hybrid equipment in the different division areas in accordance with the manner of multi-resource participation in the storage regulation and control to guide multi-resource entities to participate in regulation and control of the smart grid.

The manner of multi-resource participation in the storage regulation and control can be a manner in which an electric vehicle battery swapping station participates in the storage regulation and control.

In some embodiments, the implementation manner of the step S4 includes:
C41: if it is determined that the power storage equipment or hybrid equipment has the manner of multi-resource participation in the storage regulation and control, including a battery swapping party in the manner of multi-resource participation in the storage regulation and control, where the power storage equipment or hybrid equipment at least includes an electric vehicle battery swapping station.

In this scenario, if the power storage equipment or hybrid equipment supports the manner of multi-resource participation in the storage regulation and control, such as an electric vehicle battery swapping station, a battery swapping party is involved. The reason why an electric vehicle battery swapping station is capable of power regulation and control lies in that if the corresponding electric vehicle battery swapping station swaps fewer batteries, it indicates that it consumes less power and can be connected to the smart grid; and if the corresponding electric vehicle battery swapping station swaps more batteries, it indicates that it consumes more power and can store power. This solution can control the battery swapping strategy of the electric vehicle battery swapping station to regulate power.
C42: obtaining a first settlement price corresponding to the division areas and a power storage party, and obtaining first positioning information corresponding to the power storage equipment or hybrid equipment.

This solution requires obtaining a first settlement price corresponding to the division areas and a power storage party in addition to first positioning information corresponding to the power storage equipment or hybrid equipment. The first positioning information can be obtained by obtaining positioning information of all the power storage equipment or hybrid equipment in the division areas and then calculating the center points of all the positioning information. During the calculation, average longitude and latitude data can be used.
C43: obtaining second positioning information corresponding to power storage equipment or hybrid equipment in non-division areas.

At the same time, it is also necessary to obtain second positioning information corresponding to power storage equipment or hybrid equipment in non-division areas. The electric vehicle battery swapping stations in the division areas require power storage; in contrast, the electric vehicle battery swapping stations in the non-division areas require no power storage and their electricity settlement prices will not change.
C44: establishing an initial circular division area with an initial radius in accordance with the first positioning information.

The initial radius is, for example, 2 KM. Through this step, an initial circular division area can be established.
C45: calculating down regulation of the first settlement value in accordance with the circular division area, the first positioning information, and the second positioning information, where the first settlement value is a battery swapping price.

This solution combines the circular division area, the first positioning information, and the second positioning information to make a comprehensive determination and down-regulate the first settlement price of the battery swapping station. It can be understood that the lower the first settlement price of the battery swapping station, the more people seeking battery swapping.

In some embodiments, the implementation manner of the step C45 includes:
C451: if it is determined that the circular division area has the second positioning information, and the amount of the second positioning information is larger than or equal to a minimum amount, calculating a price adjustment coefficient.

After the circular division area is determined, it is first required to determine whether the second positioning information exists in this area, and such information corresponds to other power storage equipment or hybrid equipment in the non-division areas. If the amount of the second positioning information in the area reaches or exceeds a preset minimum amount, it indicates that down regulation can be carried out in this area. The battery swapping stations in the division areas can reduce prices, while those in the non-division areas still keep the original prices, thereby giving users a choice, and then a price adjustment coefficient is calculated. The minimum amount can be, for example, 3, 4, 5, etc.
C452: if it is determined that the circular division area does not have the second positioning information or the amount of the second positioning information is smaller than the minimum amount, enlarging the circular division area in accordance with a preset strategy to obtain an updated radius and an updated circular division area, where the preset strategy includes a preset radius magnification factor.

If no second positioning information exists in the circular division area, or the amount does not reach the minimum amount, the division areas need to be adjusted to include enough second positioning information. This adjustment is usually achieved by magnifying the radius of the circular areas. The magnification factor is preset and may be preset in accordance with different strategies and goals, such as 1.5×.
C453: if it is determined that the amount of updated second positioning information is larger than or equal to the minimum amount, calculating the price adjustment coefficient.

After the circular division area is enlarged and adjusted, the amount of the second positioning information in the area is re-evaluated. If the updated amount reaches the minimum amount, the price adjustment coefficient is calculated again.
C454: if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient.

If the amount of the second positioning information still fails to reach the minimum amount even after the enlargement adjustment, then the enlargement adjustment needs to be further performed on the division areas. This process may need to be repeated until a circular division area that includes sufficient secondary positioning information is found, at which point a valid price adjustment coefficient can be calculated.
C455: calculating the down regulation of the first settlement price in accordance with the price adjustment coefficient.

Finally, in accordance with the calculated price adjustment coefficient, the down regulation of the first settlement price (battery swapping price) is calculated. This adjustment reflects changes in market conditions and the intention of grid operators to attract more users to swap batteries at corresponding power storage equipment or hybrid equipment. After the users swap empty batteries on their electric vehicles with fully-charged batteries, the battery swapping stations will have a greater power storage capacity in the later stage.

In some embodiment, calculating the price adjustment coefficient and the down regulation of the first settlement price includes the following steps:
C4551: obtaining a first amount of the second positioning information in the circular division area, and a first separation distance between each of the second positioning information and the first positioning information.

First, the second positioning information is collected from the circular division area, and then the total amount of the second positioning information in the area is calculated. The total amount is called a first amount. At the same time, a first separation distance between each of the second positioning information and the first positioning information is calculated.
C4552: obtaining a first number of amplifications corresponding to the circular division area, calculating the price adjustment coefficient in accordance with the first amount, the first separation distance, and the first number of amplifications, and calculating the down regulation of the first settlement price in accordance with the price adjustment coefficient.

The larger the first amount, the larger the number of other available battery swapping stations, the more convenient it is, and the smaller the price adjustment coefficient needs to be; the larger the first separation distance is, the more inconvenient it is for users to swap batteries, and thus the larger the price adjustment coefficient needs to be; the larger the first number of amplifications, the more inconvenient it is for users to swap batteries, and thus the larger the price adjustment coefficient needs to be.
C4553: calculating the price adjustment coefficient and a down-regulated first settlement price by the following formula:

$${j}_{low} = {j}_{ori} - {j}_{ori} \cdot {v}_{low} , {v}_{low} = \frac{{\sum }_{U = 1}^{Y} {D}_{U}}{y} \cdot {K}_{D} + {E}_{low} \cdot {K}_{E} - {F}_{1} \cdot {K}_{F}$$

where j_{low} is the down-regulated first settlement price, jₒᵣᵢ is the original first settlement price, v_{low} is the price adjustment coefficient, F₁ is the first amount, K_{F} is a weight of the first amount, D_{U} is the first separation distance between the U-th second positioning information and the first positioning information, Y is an upper limit of the second positioning information, y is the amount of the second positioning information, K_{D} is a weight of the first separation distance, E_{low} is the first number of amplifications, and K_{E} is a weight of the first number of amplifications.

In the above formula,

$$\frac{{\sum }_{U = 1}^{Y} {D}_{U}}{y} \cdot {K}_{D}$$

is a coefficient of the distance dimension, and the larger it is, the larger the corresponding price adjustment coefficient needs to be; E_{low}·K_{E} is a coefficient of the dimension of the first number of amplifications, and the larger it is, the larger the corresponding price adjustment coefficient needs to be; and F₁·K_{F} is a coefficient of the dimension of the first amount, and the larger it is, the smaller the corresponding price adjustment coefficient needs to be. The weight of the first separation distance, the weight of the first amount, and the weight of the first number of amplifications can be preset manually.

Different from the above embodiments, this embodiment requires a battery swapping station for power supply, and the implementation manner of the step S4 includes:
D41: if it is determined that the power supply equipment or hybrid equipment has the manner of multi-resource participation in the storage regulation and control, including a battery swapping party in the manner of multi-resource participation in the storage regulation and control, where the power supply equipment or hybrid equipment at least includes an electric vehicle battery swapping station.

It is necessary to check whether there is power supply equipment or hybrid equipment (including electric vehicle battery swapping stations) that uses the manner of multi-resource participation in the storage regulation and control, which means that in addition to providing battery swapping services for electric vehicles, the battery swapping stations may also involve other forms of power supply.
D42: obtaining first positioning information corresponding to the power supply equipment or hybrid equipment.

First positioning information of such power supply equipment or hybrid equipment is collected. Since the first positioning information is obtained in the same manner as in the above embodiments, it is not elaborated herein.
D43: obtaining second positioning information corresponding to power supply equipment or hybrid equipment in non-division areas, and obtaining a second settlement price corresponding to the non-division areas of the second positioning information and a power storage party.

Second positioning information of power supply equipment or hybrid equipment in non-division areas is collected, and a second settlement price related thereto is obtained. The second settlement price is often affected by the location of the equipment, as the power supply equipment located in different areas may differ in terms of power costs, transportation costs, and ease of service.

It should be noted that since this embodiment requires a battery swapping station to be connected to the smart grid, it is necessary to reduce the number of battery swaps at the corresponding battery swapping station. Considering that the price of the battery swapping station cannot be up-regulated, the prices of the battery swapping stations in the non-division areas adjacent to the corresponding battery swapping station will be down-regulated in the future to attract users to go to the surrounding areas for battery swapping, thereby reducing the number of battery swaps at the corresponding battery swapping station.
D44: establishing an initial circular division area with an initial radius in accordance with the first positioning information.

In accordance with the collected first positioning information, an initial circular division area is established with a preset initial radius. This circular division area may be used to determine the geographical scope served by the battery swapping station or the regional scope that affects price adjustment.
D45: calculating down regulation of the second settlement values of all the second positioning information in accordance with the circular division area, the first positioning information, and the second positioning information, where the second settlement value is a battery swapping price.

This solution needs to calculate down regulation of all the involved second settlement prices (battery swapping prices) in accordance with the first positioning information and the second positioning information inside and outside the circular division area.

In some embodiments, the implementation manner of the step D45 includes:
D451: if it is determined that the circular division area has the second positioning information, and the amount of the second positioning information is larger than or equal to a minimum amount, calculating a price adjustment coefficient.
D452: if it is determined that the circular division area does not have the second positioning information or the amount of the second positioning information is smaller than the minimum amount, enlarging the circular division area in accordance with a preset strategy to obtain an updated radius and an updated circular division area, where the preset strategy includes a preset radius magnification factor.
D453: if it is determined that the amount of updated second positioning information is larger than or equal to the minimum amount, calculating the price adjustment coefficient.
D454: if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient.
D455: calculating the down regulation of the second settlement price in accordance with the price adjustment coefficient.

Since the above steps are similar in principle to the step C45, they are not elaborated herein.

In some embodiment, calculating the price adjustment coefficient and the down regulation of the second settlement price includes the following steps:
D4551: obtaining a second amount of the second positioning information in the circular division area, and a second separation distance between each of the second positioning information and the first positioning information.

First, the second positioning information is collected from the circular division area, and then the total amount of the second positioning information in the area is calculated. The total amount is called a second amount. At the same time, a second separation distance between each of the second positioning information and the first positioning information is calculated.
D4552: obtaining a second number of amplifications corresponding to the circular division area, calculating the price adjustment coefficient in accordance with the second amount, the second separation distance, and the second number of amplifications, and calculating the down regulation of the second settlement price in accordance with the price adjustment coefficient.

The larger the second amount, the larger the number of other available battery swapping stations, the more convenient it is, and the smaller the price adjustment coefficient needs to be; the larger the second separation distance is, the more inconvenient it is for users to swap batteries, and thus the larger the price adjustment coefficient needs to be; the larger the second number of amplifications, the more inconvenient it is for users to swap batteries, and thus the larger the price adjustment coefficient needs to be.
D4553: calculating the price adjustment coefficient and a down-regulated second settlement price by the following formula:

$${r}_{low} = {r}_{ori} - {r}_{ori} \cdot {c}_{low} , {c}_{low} = \frac{{\sum }_{o = 1}^{X} {Q}_{o}}{x} \cdot {B}_{Q} + {A}_{low} \cdot {B}_{A} - {F}_{2} \cdot {B}_{F}$$

where r_{low} is the down-regulated second settlement price, rₒᵣᵢ is the original second settlement price, c_{low} is the price adjustment coefficient, F₂ is the second amount, B_{F} is a weight of the second amount, Qₒ is the second separation distance between the o-th second positioning information and the first positioning information, X is an upper limit of the second positioning information, x is the amount of the second positioning information, B_{Q} is a weight of the second separation distance, A_{low} is the second number of amplifications, and B_{A} is a weight of the second number of amplifications.

In the above formula,

$$\frac{{\sum }_{o = 1}^{X} {Q}_{o}}{x} \cdot {B}_{Q}$$

is a coefficient of the distance dimension, and the larger it is, the larger the corresponding price adjustment coefficient needs to be; A_{low}·B_{A} is a coefficient of the dimension of the second number of amplifications, and the larger it is, the larger the corresponding price adjustment coefficient needs to be; and F₂·B_{F} is a coefficient of the dimension of the second amount, and the larger it is, the smaller the corresponding price adjustment coefficient needs to be. The weight of the second separation distance, the weight of the second amount, and the weight of the second number of amplifications can be preset manually.

Finally, it should be noted that the above embodiments are only used to illustrate the technical solution of the present invention rather than limiting thereto. Although the present invention has been described in detail with reference to the foregoing embodiments, those of ordinary skill in the art should understand that the technical solution recited in the foregoing embodiments may still be modified, or some or all of the technical features thereof may be replaced with equivalents. These modifications or replacements do not make the essence of the corresponding technical solution deviate from the scope of the technical solution in the embodiments of the present invention.

What is claimed is:

1. A control method for a large-scale distributed energy resource model in a smart grid, the control method comprising:
S1: obtaining energy resource types and energy resource data of corresponding distributed energy resources in the large-scale distributed energy resource model, and performing multi-level classification processing on the distributed energy resources in accordance with the energy resource types and the energy resource data to obtain corresponding power supply equipment, power storage equipment, and hybrid equipment;
S2: analyzing and processing power distribution data and load data in the smart grid to obtain a power distribution demand of the smart grid, and dividing the smart grid into different division areas in accordance with the power distribution demand of the smart grid;
S3: determining corresponding power supply equipment, power storage equipment, or hybrid equipment in accordance with the power distribution demand and the division areas of the smart grid, and performing storage regulation and control on the corresponding power supply equipment, power storage equipment, or hybrid equipment; and
S4: if it is determined that the power supply equipment, power storage equipment, or hybrid equipment has a manner of multi-resource participation in the storage regulation and control, adding different multi-resource participation pricing strategies for power supply equipment, power storage equipment, or hybrid equipment in the different division areas in accordance with the manner of multi-resource participation in the storage regulation and control to guide multi-resource entities to participate in regulation and control of the smart grid.

2. The control method of claim 1, wherein the step S1 comprises:
S11: obtaining the energy resource types of the corresponding distributed energy resources in the large-scale distributed energy resource model, wherein the energy resource types include power generation and supply information, power generation, storage, and supply information, and power storage and supply information;
S12: obtaining the energy resource data of the corresponding distributed energy resources in the large-scale distributed energy resource model, wherein the energy resource data includes grid-connectible power information and storable power information; and
S13: primarily classifying corresponding equipment in accordance with the power generation and supply information, the power generation, storage, and supply information, and the power storage and supply information to obtain power supply equipment and power storage equipment divided by function, and dividing the primarily classified power supply equipment and power storage equipment in accordance with the grid-connectible power information and the storable power information to obtain power supply equipment, power storage equipment, and hybrid equipment divided by status.

3. The control method of claim 2, wherein the primarily classifying corresponding equipment in accordance with the power generation and supply information, the power generation, storage, and supply information, and the power storage and supply information to obtain power supply equipment and power storage equipment divided by function, and dividing the primarily classified power supply equipment and power storage equipment in accordance with the grid-connectible power information and the storable power information to obtain power supply equipment, power storage equipment, and hybrid equipment divided by status comprises:
if it is determined that equipment of the distributed energy resources is the power generation and supply information, primarily classifying the corresponding equipment as the power supply equipment; if it is determined that equipment of the distributed energy resources is the power generation, storage, and supply information, primarily classifying the corresponding equipment as the power supply equipment, and adding a secondary classification tag; if it is determined that equipment of the distributed energy resources is the power storage and supply information, primarily classifying the corresponding equipment as the power storage equipment, and adding a secondary classification tag; and analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status.

4. The control method of claim 3, wherein the analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status comprises:
obtaining the storable power information of the power supply equipment in the secondary classification tag;
if it is determined that the storable power information is 0, taking the corresponding power supply equipment as secondarily classified power supply equipment; and
if it is determined that the storable power information is larger than 0, taking the corresponding power supply equipment as secondarily classified hybrid equipment.

5. The control method of claim 3, wherein the analyzing the grid-connectible power information or the storable power information of the power supply equipment and the power storage equipment with the added secondary classification tag, and secondarily classifying corresponding power supply equipment and power storage equipment to obtain the power supply equipment, the power storage equipment, and the hybrid equipment divided by status comprises:
obtaining the grid-connectible power information and the storable power information of the power storage equipment in the secondary classification tag;
if it is determined that the storable power information is 0, taking the corresponding power storage equipment as secondarily classified power supply equipment; and
if it is determined that the grid-connectible power information is 0, taking the corresponding power storage equipment as secondarily classified power storage equipment; and
if it is determined that neither the storable power information nor the grid-connectible power information is 0, taking the corresponding power supply equipment as secondarily classified hybrid equipment.

6. The control method of claim 1, wherein the step S2 comprises:
S21: if it is determined that the power distribution data in the smart grid is larger than the load data, taking the power distribution demand of the smart grid as a power storage demand;
S22: if it is determined that the power distribution data in the smart grid is smaller than the load data, taking the power distribution demand of the smart grid as a grid connection demand; and
S23: obtaining power lines in the smart grid, segmenting the power lines in accordance with a preset distance to obtain different power distribution areas, and dividing the smart grid into the different division areas in accordance with the power storage demand or the grid connection demand.

7. The control method of claim 6, wherein the obtaining power lines in the smart grid, segmenting the power lines in accordance with a preset distance to obtain different power distribution areas, and dividing the smart grid into the different division areas in accordance with the power storage demand or the grid connection demand comprises:
obtaining load information in the different power distribution areas of the different areas of the smart grid in accordance with the load data;
calculating a power supply distance between each of the power distribution areas and a power supply source if it is determined that the power distribution demand of the smart grid is the power storage demand, and sorting the power distribution areas in accordance with the power supply distance and the load information to obtain a load demand sequence and the number of the areas;
sorting all the power distribution areas in descending order in accordance with the load information to obtain a load demand sequence and the number of the areas if it is determined that the power distribution demand of the smart grid is the grid connection demand; and
selecting corresponding power distribution areas in the load demand sequence as the division areas in accordance with the number of the areas.

8. The control method of claim 7, wherein the calculating a power supply distance between each of the power distribution areas and a power supply source if it is determined that the power distribution demand of the smart grid is the power storage demand, and sorting the power distribution areas in accordance with the power supply distance and the load information to obtain a load demand sequence and the number of the areas comprises:
obtaining a first endpoint of each of the power distribution areas on a side close to the power supply source, calculating a distance between the first endpoint and the power supply source to obtain the power supply distance between the corresponding power distribution area and the power supply source, and weighting the power supply distance in accordance with a distance weight to obtain a distance coefficient;
comparing a preset constant value with the load information to obtain a first proportional value, and weighting the first proportional value in accordance with a load weight to obtain a load coefficient;
adding the distance coefficient and the load coefficient together to obtain a first sorting coefficient, sorting the power distribution areas in ascending order in accordance with the first sorting coefficient to obtain the load demand sequence, and calculating a difference between the power distribution data and the load data to obtain the number of the areas; and
selecting corresponding areas in the load demand sequence in accordance with the number of the areas to obtain the different division areas.

9. The control method of claim 8, wherein the adding the distance coefficient and the load coefficient together to obtain a first sorting coefficient, sorting the power distribution areas in ascending order in accordance with the first sorting coefficient to obtain the load demand sequence, and calculating a difference between the power distribution data and the load data to obtain the number of the areas comprises:
calculating the first sorting coefficient and the number of the areas by the following formula:
$${p}_{1} = l \cdot {k}_{l} + \frac{u}{a} \cdot {k}_{u} , {s}_{1} = {z}_{1} + \frac{{w}_{1} - {w}_{2}}{{m}_{1}}$$
wherein p₁ is the first sorting coefficient, l is the power supply distance, kₗ is the distance weight, u is the preset constant value, a is the load information of the corresponding power distribution areas when the power distribution demand is the power storage demand, kᵤ is the load weight, s₁ is the number of the areas when the power distribution demand is the power storage demand, z₁ is a first basic number, w₁ is an electrical power value of the power distribution data, w₂ is an electrical power value of the load data, and m₁ is a first load normalization value.

10. The control method of claim 7, wherein the sorting all the power distribution areas in descending order in accordance with the load information to obtain a load demand sequence and the number of the areas if it is determined that the power distribution demand of the smart grid is the grid connection demand comprises:
calculating the number of the areas by the following formula:
$${s}_{2} = {z}_{2} + \frac{{w}_{2} - {w}_{1}}{{m}_{2}}$$
wherein s₂ is the number of the areas when the power distribution demand is the grid connection demand, z₂ is a second basic number, and m₂ is a second load normalization value.

11. The control method of claim 1, wherein the step S3 comprises:
A31: if it is determined that the power distribution demand of the smart grid is the power storage demand, determining the corresponding power storage equipment or hybrid equipment in the division areas;
A32: sorting in descending order to obtain a corresponding power storage sequence in accordance with the storable power information of the corresponding power storage equipment or hybrid equipment; and
A33: selecting power storage equipment or hybrid equipment within the power storage sequence in accordance with a storage demand value in the power storage demand, and performing the storage regulation and control on the selected power storage equipment or hybrid equipment in accordance with a power storage command when the storable power information of the corresponding power storage equipment or hybrid equipment is larger than or equal to the storage demand value.

12. The control method of claim 1, wherein the step S3 comprises:
B31: if it is determined that the power distribution demand of the smart grid is the grid connection demand, determining the corresponding power supply equipment or hybrid equipment in the division areas;
B32: sorting in descending order to obtain a corresponding grid connection sequence in accordance with the grid-connectible power information of the corresponding power supply equipment or hybrid equipment;
B33: selecting power supply equipment or hybrid equipment within the grid connection sequence in accordance with a grid connection value in the grid connection demand, and performing the storage regulation and control on the selected power supply equipment or hybrid equipment in accordance with a grid connection command when the grid connection information of the corresponding power supply equipment or hybrid equipment is larger than or equal to the grid connection demand value.

13. The control method of claim 11, wherein the step S4 comprises:
C41: if it is determined that the power storage equipment or hybrid equipment has the manner of multi-resource participation in the storage regulation and control, including a battery swapping party in the manner of multi-resource participation in the storage regulation and control, wherein the power storage equipment or hybrid equipment at least includes an electric vehicle battery swapping station;
C42: obtaining a first settlement price corresponding to the division areas and a power storage party, and obtaining first positioning information corresponding to the power storage equipment or hybrid equipment;
C43: obtaining second positioning information corresponding to power storage equipment or hybrid equipment in non-division areas;
C44: establishing an initial circular division area with an initial radius in accordance with the first positioning information; and
C45: calculating down regulation of the first settlement value in accordance with the circular division area, the first positioning information, and the second positioning information, wherein the first settlement value is a battery swapping price.

14. The control method of claim 13, wherein the calculating down regulation of the first settlement value in accordance with the circular division area, the first positioning information, and the second positioning information comprises:
if it is determined that the circular division area has the second positioning information, and the amount of the second positioning information is larger than or equal to a minimum amount, calculating a price adjustment coefficient;
if it is determined that the circular division area does not have the second positioning information or the amount of the second positioning information is smaller than the minimum amount, enlarging the circular division area in accordance with a preset strategy to obtain an updated radius and an updated circular division area, wherein the preset strategy comprises a preset radius magnification factor;
if it is determined that the amount of updated second positioning information is larger than or equal to the minimum amount, calculating the price adjustment coefficient;
if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient; and
calculating the down regulation of the first settlement price in accordance with the price adjustment coefficient.

15. The control method of claim 14, wherein the calculating the price adjustment coefficient and the down regulation of the first settlement price comprises:
obtaining a first amount of the second positioning information in the circular division area, and a first separation distance between each of the second positioning information and the first positioning information;
obtaining a first number of amplifications corresponding to the circular division area, calculating the price adjustment coefficient in accordance with the first amount, the first separation distance, and the first number of amplifications, and calculating the down regulation of the first settlement price in accordance with the price adjustment coefficient; and
calculating the price adjustment coefficient and a down-regulated first settlement price by the following formula:
$${j}_{low} = {j}_{ori} - {j}_{ori} \cdot {v}_{low} , {v}_{low} = \frac{{\sum }_{U = 1}^{Y} {D}_{U}}{y} \cdot {K}_{D} + {E}_{low} \cdot {K}_{E} - {F}_{1} \cdot {K}_{F}$$
wherein j_{low} is the down-regulated first settlement price, jₒᵣᵢ is the original first settlement price, v_{low} is the price adjustment coefficient, F₁ is the first amount, K_{F} is a weight of the first amount, D_{U} is the first separation distance between the U-th second positioning information and the first positioning information, Y is an upper limit of the second positioning information, y is the amount of the second positioning information, K_{D} is a weight of the first separation distance, E_{low} is the first number of amplifications, and K_{E} is a weight of the first number of amplifications.

16. The control method of claim 12, wherein the step S4 comprises:
D41: if it is determined that the power supply equipment or hybrid equipment has the manner of multi-resource participation in the storage regulation and control, including a battery swapping party in the manner of multi-resource participation in the storage regulation and control, wherein the power supply equipment or hybrid equipment at least includes an electric vehicle battery swapping station;
D42: obtaining first positioning information corresponding to the power supply equipment or hybrid equipment;
D43: obtaining second positioning information corresponding to power supply equipment or hybrid equipment in non-division areas, and obtaining a second settlement price corresponding to the non-division areas of the second positioning information and a power storage party;
D44: establishing an initial circular division area with an initial radius in accordance with the first positioning information; and
D45: calculating down regulation of the second settlement values of all the second positioning information in accordance with the circular division area, the first positioning information, and the second positioning information, wherein the second settlement value is a battery swapping price.

17. The control method of claim 16, wherein the calculating down regulation of the second settlement values of all the second positioning information in accordance with the circular division area, the first positioning information, and the second positioning information comprises:
if it is determined that the circular division area has the second positioning information, and the amount of the second positioning information is larger than or equal to a minimum amount, calculating a price adjustment coefficient;
if it is determined that the circular division area does not have the second positioning information or the amount of the second positioning information is smaller than the minimum amount, enlarging the circular division area in accordance with a preset strategy to obtain an updated radius and an updated circular division area, wherein the preset strategy comprises a preset radius magnification factor;
if it is determined that the amount of updated second positioning information is larger than or equal to the minimum amount, calculating the price adjustment coefficient;
if it is determined that the updated circular division area does not have the second positioning information or the amount of the second positioning information is smaller than the minimum amount, enlarging the circular division area again in accordance with the preset strategy until the amount of the second positioning information in the updated circular division area is larger than or equal to the minimum amount, and then calculating the price adjustment coefficient; and
calculating the down regulation of the second settlement price in accordance with the price adjustment coefficient.

18. The control method of claim 17, wherein the calculating the price adjustment coefficient and the down reduction of the second settlement price comprises the following steps:
obtaining a second amount of the second positioning information in the circular division area, and a second separation distance between each of the second positioning information and the first positioning information;
obtaining a second number of amplifications corresponding to the circular division area, calculating the price adjustment coefficient in accordance with the second amount, the second separation distance, and the second number of amplifications, and calculating the down regulation of the second settlement price in accordance with the price adjustment coefficient; and
calculating the price adjustment coefficient and a down-regulated second settlement price by the following formula:
$${r}_{low} = {r}_{ori} - {r}_{ori} \cdot {c}_{low} , {c}_{low} = \frac{{\sum }_{o = 1}^{X} {Q}_{o}}{x} \cdot {B}_{Q} + {A}_{low} \cdot {B}_{A} - {F}_{2} \cdot {B}_{F}$$
wherein r_{low} is the down-regulated second settlement price, rₒᵣᵢ is the original second settlement price, c_{low} is the price adjustment coefficient, F₂ is the second amount, B_{F} is a weight of the second amount, Qₒ is the second separation distance between the o-th second positioning information and the first positioning information, X is an upper limit of the second positioning information, x is the amount of the second positioning information, B_{Q} is a weight of the second separation distance, A_{low} is the second number of amplifications, and B_{A} is a weight of the second number of amplifications.
